(19) United States
(12) Patent Application Publication
(10) Pub. No.: US 2026/0143949 A1
(43) Pub. Date: May 21, 2026

(54) DISPLAY SUBSTRATE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Junxiu DAI, Beijing (CN); Yang ZHOU, Beijing (CN); Lu BAI, Beijing (CN); Yi QU, Beijing (CN); Song LIU, Beijing (CN); Bo ZHANG, Beijing (CN); Dongjie WU, Beijing (CN); Kai ZHANG, Beijing (CN); Ming HU, Beijing (CN); Wenbo HU, Beijing (CN); Gang WANG, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/705,974

(22) PCT Filed: Mar. 23, 2023
(86) PCT No.: PCT/CN2023/083379

§ 371 Date: Apr. 29, 2024

(30) Foreign Application Priority Data
Mar. 25, 2022 (CN) 202210307455.2

(51) Int. Cl. H10K 59/80; G01N 27/20; H10D 86/40; H10K 59/126; H10K 59/131

(52) U.S. Cl. CPC H10K 59/873; G01N 27/20; H10D 86/481; H10K 59/126; H10K 59/131

(57) ABSTRACT

A display substrate is provided. The display substrate has a display region and a peripheral region at least partially surrounding the display region, and includes: a base substrate, a first barrier dam, a first power signal line, a crack detection circuit, and a crack detection circuit, an orthographic projection of at least part of a boundary of the first power signal line away from the display region on the base substrate is located inside an orthographic projection of the first barrier dam on the base substrate; and an orthographic projection of the crack detection circuit on the base substrate at least partially overlaps with an orthographic projection of the first barrier dam on the base substrate.

### CROSS-REFERENCE TO RELATED APPLICATION

The present application claims the priority of the Chinese patent application No. 202210307455.2 filed on Mar. 25, 2022, the disclosure of which is incorporated herein by reference in its entirety as part of the present application.

### TECHNICAL FIELD

The embodiments of the present disclosure relate to a display substrate.

### BACKGROUND

Organic light emitting diode (OLED) display devices have a series of advantages, such as self-luminescence, high contrast, high definition, wide viewing angle, low power consumption, fast response and low manufacturing cost, etc., have become one of the key development directions of the new generation of display devices, and have attracted more and more attention. At present, OLED display devices are developing in the direction of narrow border and large screen to meet the needs of users.

### SUMMARY

At least one embodiment of the present disclosure provides a display substrate, the display substrate has a display region and a peripheral region at least partially surrounding the display region, and comprises: a base substrate, a first barrier dam, a first power signal line, and a crack detection circuit, the first barrier dam is on the base substrate and in the peripheral region, and at least partially surrounds the display region; the first power signal line is between the base substrate and the first barrier dam and extends at least in the peripheral region, an orthographic projection of at least part of a boundary of the first power signal line away from the display region on the base substrate is located inside an orthographic projection of the first barrier dam on the base substrate; the crack detection circuit is between the base substrate and the first barrier dam, in the peripheral region, and at least partially surrounds the display region, an orthographic projection of the crack detection circuit on the base substrate at least partially overlaps with an orthographic projection of the first barrier dam on the base substrate.

For example, in the display substrate provided by at least one embodiment of the present disclosure, the crack detection circuit comprises a first wiring portion on the base substrate and a second wiring portion on a side of the first wiring portion away from the base substrate, the second wiring portion is electrically connected with the first wiring portion through a via, an orthographic projection of the second wiring portion on the base substrate is located inside the orthographic projection of the first barrier dam on the base substrate.

For example, in the display substrate provided by at least one embodiment of the present disclosure, the second wiring portion is in a same layer as the first power signal line.

For example, in the display substrate provided by at least one embodiment of the present disclosure, the second wiring portion is on a side of the first power signal line away from the display region, and the first wiring portion is on a side of the second wiring portion away from the display region.

For example, in the display substrate provided by at least one embodiment of the present disclosure, the first wiring portion comprises a plurality of first wires, an orthographic projection of a boundary of the first barrier dam away from the display region on the base substrate is located inside an orthographic projection of the plurality of first wires on the base substrate, or the orthographic projection of the boundary of the first barrier dam away from the display region on the base substrate is located inside an orthographic projection of an interval between two adjacent first wires among the plurality of first wires on the base substrate.

For example, in the display substrate provided by at least one embodiment of the present disclosure, the orthographic projection of the boundary of the first barrier dam away from the display region on the base substrate is located in a middle portion of an orthographic projection of one of the plurality of first wires on the base substrate, or the orthographic projection of the boundary of the first barrier dam on the base substrate is located inside the orthographic projection of the interval between two adjacent first wires among the plurality of first wires on the base substrate, and a distance between the orthographic projection of the boundary of the first barrier dam on the base substrate and an orthographic projection of a first wire, away from the display region, among the two adjacent first wires is greater than or equal to 3 microns.

For example, in the display substrate provided by at least one embodiment of the present disclosure, the display region comprises a plurality of sub-pixels, and each of the plurality of sub-pixels comprises a light emitting device and a pixel driving circuit for driving the light emitting device, the pixel driving circuit comprises a thin film transistor and a storage capacitor, the thin film transistor comprises a gate electrode on the base substrate and a source-drain electrode on a side of the gate electrode away from the base substrate, the storage capacitor comprises a first capacitor electrode on the base substrate and a second capacitor electrode on a side of the first capacitor electrode away from the base substrate, the gate electrode and the first capacitor electrode are in a same layer, the second capacitor electrode and the first wiring portion are in a same layer, and the source-drain electrode and the second wiring portion are in a same layer.

For example, the display substrate provided by at least one embodiment of the present disclosure further comprises a crack barrier dam, the crack barrier dam is on a side of the crack detection circuit away from the display region.

For example, in the display substrate provided by at least one embodiment of the present disclosure, the peripheral region comprises an inorganic layer, and the crack barrier dam comprises a groove in the inorganic layer.

For example, in the display substrate provided by at least one embodiment of the present disclosure, the display region further comprises a planarization layer on a side of the pixel driving circuit away from the base substrate, a pixel definition layer on a side of the planarization layer away from the base substrate, and a spacer on a side of the pixel definition layer away from the base substrate, the first barrier dam is in a same layer as at least one of the planarization layer, the pixel definition layer and the spacer.

For example, in the display substrate provided by at least one embodiment of the present disclosure, an orthographic projection of at least part of a boundary of the crack detection circuit away from the display region on the base substrate is located inside the orthographic projection of the first barrier dam on the base substrate.

For example, in the display substrate provided by at least one embodiment of the present disclosure, the orthographic projection of the crack detection circuit on the base substrate at least partially overlaps with an orthographic projection of the first power signal line on the base substrate.

For example, in the display substrate provided by at least one embodiment of the present disclosure, the first power signal line is on a side of the crack detection circuit away from the base substrate.

For example, in the display substrate provided by at least one embodiment of the present disclosure, the peripheral region further comprises at least one auxiliary wire, and the first power signal line is electrically connected with the at least one auxiliary wire through a via to be connected in parallel with the at least one auxiliary wire.

For example, in the display substrate provided by at least one embodiment of the present disclosure, the display region comprises a plurality of sub-pixels, and each of the plurality of sub-pixels comprises a light emitting device and a pixel driving circuit for driving the light emitting device, the pixel driving circuit comprises a thin film transistor and a storage capacitor, the thin film transistor comprises a gate electrode on the base substrate and a source-drain electrode on a side of the gate electrode away from the base substrate, the storage capacitor comprises a first capacitor electrode on the base substrate and a second capacitor electrode on a side of the first capacitor electrode away from the base substrate, the gate electrode and the first capacitor electrode are in a same layer, the second capacitor electrode and the at least one auxiliary wire are in a same layer, and the source-drain electrode and the first power signal line are in a same layer.

For example, in the display substrate provided by at least one embodiment of the present disclosure, the crack detection circuit and the at least one auxiliary wire are in a same layer.

For example, in the display substrate provided by at least one embodiment of the present disclosure, the thin film transistor further comprises an active layer, the active layer is on a side of the gate electrode close to the base substrate, and the display region further comprises a light shielding pattern, the light shielding pattern is between the active layer and the base substrate, and an orthographic projection of the active layer on the base substrate at least partially overlaps with an orthographic projection of the light shielding pattern on the base substrate.

For example, in the display substrate provided by at least one embodiment of the present disclosure, the crack detection circuit and the light shielding pattern are in a same layer.

For example, in the display substrate provided by at least one embodiment of the present disclosure, the orthographic projection of the crack detection circuit on the base substrate at least partially overlaps with an orthographic projection of the at least one auxiliary wire on the base substrate.

For example, the display substrate provided by at least one embodiment of the present disclosure further comprises a crack barrier dam, the crack barrier dam is in the peripheral region and on a side of the first barrier dam close to the display region, and at least partially surrounding the display region, an orthographic projection of the crack barrier dam on the base substrate at least partially overlaps with the orthographic projection of the first power signal line on the base substrate.

For example, in the display substrate provided by at least one embodiment of the present disclosure, the crack barrier dam is in a same layer as at least one of the gate electrode and the second capacitor electrode.

For example, in the display substrate provided by at least one embodiment of the present disclosure, in an extending direction of the crack barrier dam, the crack barrier dam comprises a plurality of sub-crack barrier dams arranged at intervals.

For example, in the display substrate provided by at least one embodiment of the present disclosure, in the extending direction of the crack barrier dam, a length of each of the plurality of sub-crack barrier dams is less than 50 mm.

For example, the display substrate provided by at least one embodiment of the present disclosure further comprises: a second barrier dam, on a side of the first barrier dam close to the display region and on a side of the crack barrier dam away from the base substrate, the orthographic projection of the crack barrier dam on the base substrate at least partially overlaps with an orthographic projection of the second barrier dam on the base substrate.

For example, in the display substrate provided by at least one embodiment of the present disclosure, the first power signal line is configured to provide a first power signal to the display region, the display substrate further comprises a second power signal line, the second power supply signal line is configured to provide a second power signal to the display region, a potential of the second power signal is higher than a potential of the first power signal.

### BRIEF DESCRIPTION OF DRAWINGS

In order to clearly illustrate technical solutions of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a schematic diagram of a circuit and structure arrangement of a peripheral region of a display substrate.

FIG. 2 is a schematic plan view of a display substrate provided by at least one embodiment of the present disclosure.

FIG. 3 is an enlarged schematic view of a display substrate in FIG. 2 in a dashed frame region.

FIG. 4 is a schematic cross-sectional view of a display substrate in FIG. 3 along a line A-A.

FIG. 5A is a partial schematic cross-sectional view of a sub-pixel of a display region of a display substrate provided by at least one embodiment of the present disclosure.

FIG. 5B is another partial schematic cross-sectional view of a sub-pixel of a display region of a display substrate provided by at least one embodiment of the present disclosure.

FIG. 6A is another enlarged schematic view of a display substrate in FIG. 2 in a dashed frame region.

FIG. 6B is a schematic cross-sectional view of a display substrate in FIG. 6A along a line B-B.

FIG. 7A is another enlarged schematic view of a display substrate in FIG. 2 in a dashed frame region.

FIG. 7B is a schematic cross-sectional view of a display substrate in FIG. 7A along a line D-D.

FIG. 8A is yet another enlarged schematic view of a display substrate in FIG. 2 in a dashed frame region.

FIG. 8B is a schematic cross-sectional view of a display substrate in FIG. 8A along a line E-E.

FIG. 9 is a scanning electron microscope diagram of a display substrate in which an encapsulation layer is broken around a first wire.

FIG. 10 is a schematic plan view of another display substrate provided by at least one embodiment of the present disclosure.

FIG. 11 is a schematic cross-sectional view of a display substrate in FIG. 10 along a line C-C.

FIG. 12 is another schematic cross-sectional view of a display substrate in FIG. 10 along a line C-C.

FIG. 13 is another partial schematic cross-sectional view of a sub-pixel in a display region of a display substrate provided by at least one embodiment of the present disclosure.

FIG. 14 is another schematic cross-sectional view of a display substrate in FIG. 10 along a line C-C.

FIG. 15 is an enlarged schematic view of a display substrate in FIG. 10 in a dashed frame region.

FIG. 16 is yet another schematic cross-sectional view of a display substrate in FIG. 10 along a line C-C.

FIG. 17 is a schematic diagram of a circuit and structure arrangement of a peripheral region of a display substrate provided by at least one embodiment of the present disclosure.

### DETAILED DESCRIPTION

In order to make objectives, technical details, and advantages of the embodiments of the present disclosure clearer, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the position of the object which is described is changed, the relative position relationship may be changed accordingly.

In a display panel, how to further narrow a border and ensure an encapsulation reliability of the display panel under the narrow border is the common effort direction of those skilled in the art.

In the display panel, a panel crack detection circuit (PCD) is usually set to detect whether there is a crack in the display panel. The circuit pattern in the crack detection circuit needs to be protected by a protective layer. There are two common protective layers, one is an organic protective layer, and another is an inorganic protective layer. In the case of using the organic protective layer, an inorganic layer is usually needed to cover the organic protective layer, to avoid undesirable phenomena such as water absorption and expansion of the organic protective layer. However, in an actual process, because of process fluctuation, a thickness of the inorganic layer is often insufficient, and the inorganic layer is easy to break at a position with a slit, which leads to an exposure of the organic protective layer, which in turn leads to water absorption expansion and encapsulation failure. In the case of using the inorganic protective layer, it is needed to add a depositing process of inorganic materials to prepare the inorganic protective layer, that is, one preparation process is added, which will reduce the productivity.

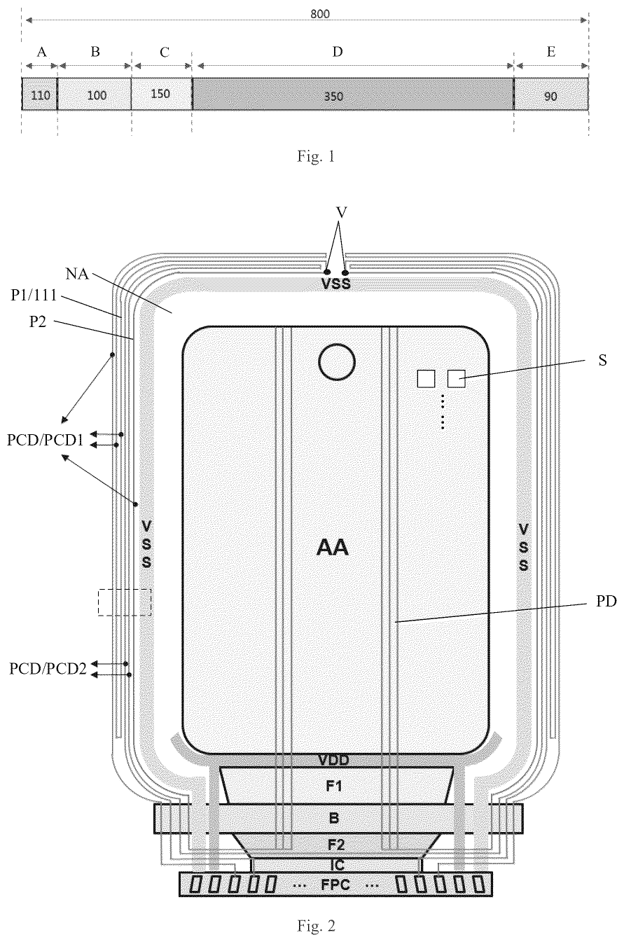

In addition, when designing a narrow border, for example, FIG. 1 shows a border of a display substrate, that is, a schematic diagram of a structural arrangement of a non-display region around a display region. As illustrated by FIG. 1, in some display substrates with the narrow border, the non-display region is provided with an edge cutting region A, a crack blocking region B, a power supply routing region C, a circuit setting region D and a connection region E.

The edge cutting region A is a region reserved for the cutting operation for forming a single display substrate by cutting a mother substrate, and a width of the edge cutting region is usually about 110 microns; the crack blocking region B is provided with a crack blocking structure and a crack detection circuit to cope with the formation of cracks in the display substrate that may be caused by the cutting operation for forming a single display substrate by cutting, and a width of the crack blocking region is usually about 100 microns; the power supply routing region C is, for example, a setting region of the power supply bus for transmitting low-level voltage signals to a plurality of sub-pixels in the display region, and a width of the power supply routing region is usually about 150 microns; the circuit setting region D is a setting region of a gate on array (GOA) driving circuit that provides driving signals to the pixel driving circuits of the plurality of sub-pixels in the display region, and a width of the circuit setting region is usually about 350 microns; the connection region E is an region where structures of the peripheral region (such as wires and circuits) are connected with structures of the display region (such as wires and circuits), and a width of the connection region is usually about 90 microns.

A sum of the widths of the above regions is the width of the border of the display substrate, which is about 850 microns. The width is basically a narrowest width achieved by precise design on the basis of realizing the basic functions of the circuits and functional structures of each region, and it is difficult to further reduce the width, so it is a greater challenge for technicians to further narrow the border.

At least one embodiment of the present disclosure provides a display substrate, the display substrate has a display region and a peripheral region at least partially surrounding the display region, and includes a base substrate, a first barrier dam, a first power signal line and a crack detection circuit, the first barrier dam is arranged on the base substrate and in the peripheral region, and at least partially surrounds the display region; the first power signal line is arranged between the base substrate and the first barrier dam and extends at least in the peripheral region, and an orthographic projection of at least part of a boundary of the first power signal line away from the display region on the base substrate is located inside an orthographic projection of the first barrier dam on the base substrate; the crack detection circuit is arranged between the base substrate and the first barrier dam, and is arranged in the peripheral region and at least partially surrounds the display region, and an orthographic projection of the crack detection circuit on the base substrate at least partially overlaps with an orthographic projection of the first barrier dam on the base substrate.

In the display substrate provided by the embodiments of the present disclosure, by designing the positional relationship between the crack detection circuit and the first power signal line and the first barrier dam nearby, the border of the display substrate can be further narrowed, for example, the width of the border can be reduced to below 720 microns, for example, an extremely narrow border design with the width of 600 microns or 650 microns can be realized; moreover, the first barrier dam can be used for protecting the crack detection circuit while achieving the barrier function, and be beneficial to the subsequent encapsulation process and improve the encapsulation reliability.

The display substrate of the present disclosure will be described below through several specific embodiments.

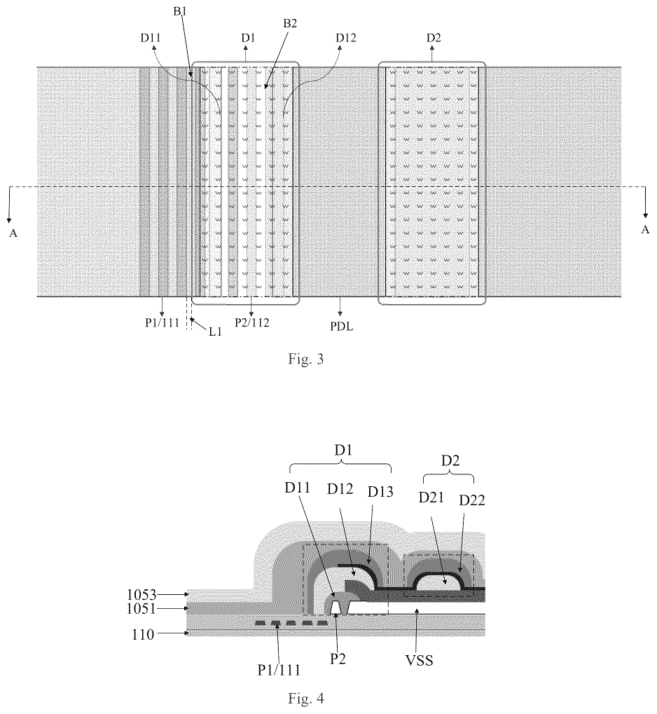

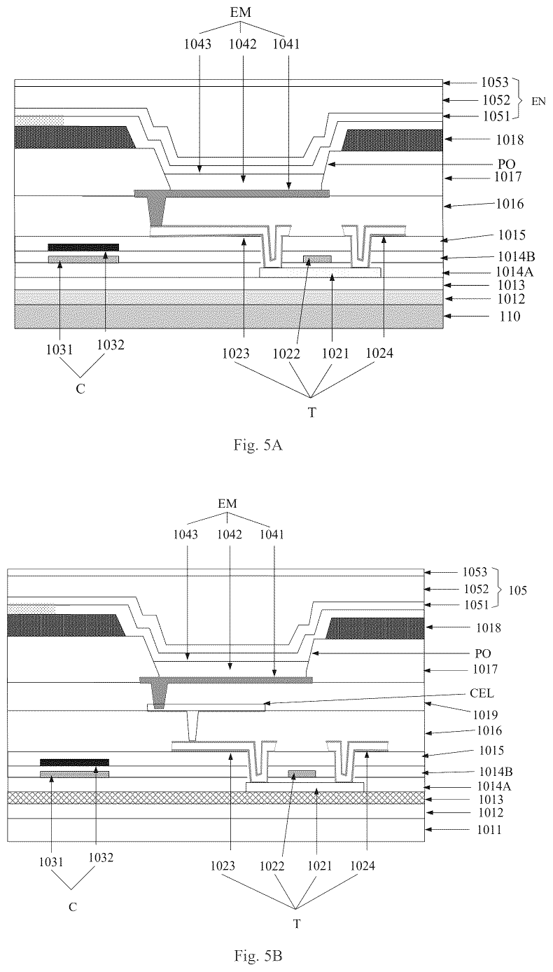

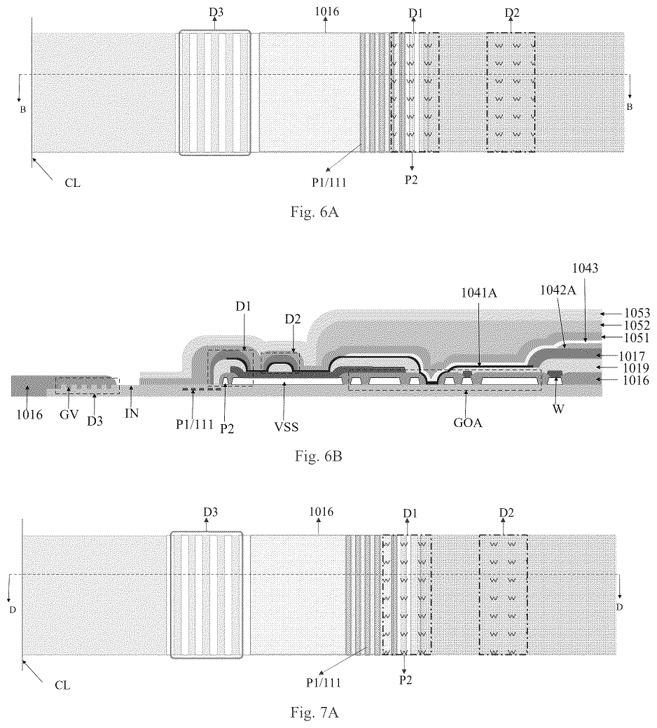

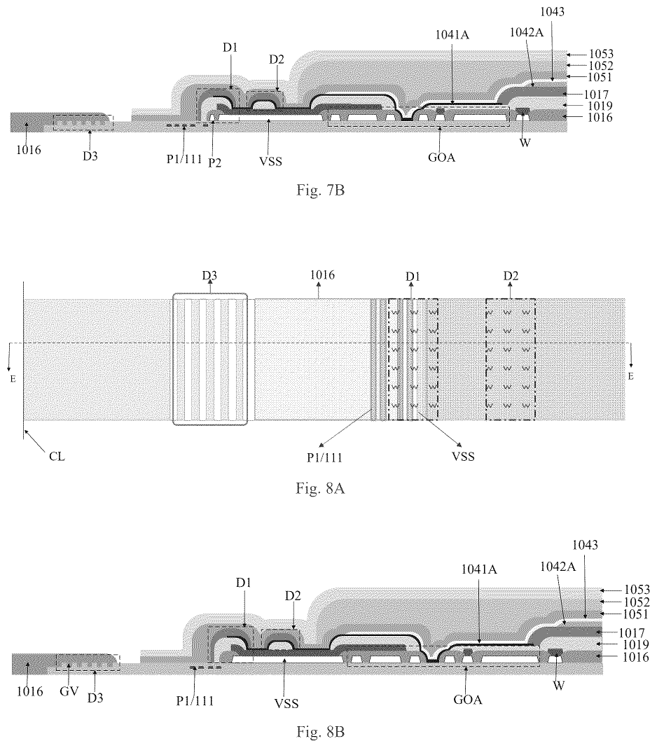

At least one embodiment of the present disclosure provides a display substrate, and FIG. 2 shows a schematic plan view of the display substrate, FIG. 3 shows an enlarged schematic view of a display substrate in FIG. 2 in a dashed frame region, and FIG. 4 shows a schematic cross-sectional view of a display substrate in FIG. 3 along a line A-A. As illustrated by FIGS. 2-4, the display substrate includes a display region AA and a peripheral region NA at least partially surrounding the display region AA, and includes a base substrate 110, a first barrier dam D1, a first power signal line VSS and a crack detection circuit PCD.

The first barrier dam D1 is arranged on the base substrate 110 and in the peripheral region NA, and at least partially surrounds the display region AA, for example, surrounds the display region AA on four sides of the display region AA, so as to block materials formed (e.g., inkjet printed) in the display region AA from flowing into the peripheral region NA. The first power signal line VSS is arranged between the base substrate 110 and the first barrier dam D1, and extends at least in the peripheral region NA, for example, extends from the display region AA to the peripheral region NA in some embodiments. An orthographic projection of at least part of a boundary B2 of the first power signal line VSS away from the display region AA on the base substrate 110 is located inside an orthographic projection of the first barrier dam D1 on the base substrate 110. Thus, the first barrier dam D1 covers the at least part of the boundary B2 of the first power signal line VSS away from the display region AA to protect the first power signal line VSS.

The crack detection circuit PCD is arranged between the base substrate 110 and the first barrier dam D1, and is arranged in the peripheral region NA and at least partially surrounds the display region AA, for example, surrounding the display region AA at left, upper and right sides of the display region AA, the crack detection circuit PCD can detect whether the display substrate has undesirable phenomena such as fracture due to cutting.

An orthographic projection of the crack detection circuit PCD on the base substrate 110 at least partially overlaps with an orthographic projection of the first barrier dam D1 on the base substrate 110, so that the first barrier dam D1 can further protect at least part of the crack detection circuit PCD, and it is unneeded to form an additional protective layer to protect the crack detection circuit PCD, thereby simplifying the manufacturing process of the display substrate. In addition, the above arrangement can further shorten a distance from the first barrier dam D1 to a cutting line CL (refer to FIGS. 6A, 7A and 8A) to further narrow the border.

For example, in some embodiments, the crack detection circuit PCD includes a first wiring portion P1 arranged on the base substrate 110 and a second wiring portion P2 arranged on a side of the first wiring portion P1 away from the base substrate 110, the second wiring portion P2 is electrically connected with the first wiring portion P1 through a via V, and an orthographic projection of the second wiring portion P2 on the base substrate 110 is located inside the orthographic projection of the first barrier dam D1 on the base substrate 110. For example, the first barrier dam D1 can be directly arranged on the second wiring portion P2 to contact with the second wiring portion P2, so as to realize the protection function.

In the embodiments of the present disclosure, the crack detection circuit PCD is arranged to include the first wiring portion P1 and the second wiring portion P2 which are electrically connected and located in different conductive layers, so that undesirable phenomena such as electrostatic interference can be prevented from occurring in relatively long wire (long-distance wire), thereby achieving the antistatic effect.

For example, in some embodiments, the second wiring portion P2 is arranged in the same layer as the first power signal line VSS to simplify the manufacturing process of the display substrate.

It should be noted that, in the embodiments of the present disclosure, “in the/a same layer” means that two functional layers or structural layers are in the same layer and formed of the same material in the hierarchical structure of the display substrate, that is, in the manufacturing process, the two functional layers or structural layers can be formed of the same material layer, and the required patterns and structures can be formed by the same patterning process.

For example, in some embodiments, the second wiring portion P2 is arranged on a side of the first power signal line VSS away from the display region AA, and the first wiring portion P1 is arranged on a side of the second wiring portion P2 away from the display region AA. That is, the first wiring portion P1, the second wiring portion P2 and the first power signal line VSS are sequentially arranged in a direction close to the display region AA.

For example, in some embodiments, the first wiring portion P1 includes a plurality of first wires 111 (i.e., a number of the first wires arranged side by side on a side of the display substrate), such as two to six first wires 111, and the second wiring portion P2 includes at least one second wire 112 (i.e., a number of the second wires arranged side by side on a side of the display substrate), such as one to three second wires 112. The embodiments of the present disclosure are not specifically limited in this aspect.

For example, an orthographic projection of a boundary B1 of the first barrier dam D1 away from the display region AA on the base substrate 110 is located inside an orthographic projection of the plurality of first wires 111 on the base substrate, that is, the boundary B1 of the first barrier dam D1 away from the display region AA is located right above any one of the plurality of first wires 111; alternatively, in other embodiments, the orthographic projection of the boundary B1 of the first barrier dam D1 away from the display region AA on the base substrate 110 is located inside an orthographic projection of an interval between two adjacent first wires 111 among the plurality of first wires 111 on the base substrate 110, that is, the boundary B1 of the first barrier dam D1 away from the display region AA is located right above the interval between the first wires 111.

For example, in some embodiments, the orthographic projection of the boundary B1 of the first barrier dam D1 away from the display region AA on the base substrate 110 is located in the middle portion of the orthographic projection of one of the first wires 111 on the base substrate 110, as illustrated by FIG. 6A, the boundary B1 of the first barrier dam D1 away from the display region AA is located right above the middle portion of one of the first wires 111; alternatively, in some other embodiments, as illustrated by FIG. 3, the orthographic projection of the boundary B1 of the first barrier dam D1 on the base substrate 110 is located inside the orthographic projection of the interval between two adjacent first wires 111 among the plurality of first wires 111 on the base substrate 110, and a distance L1 between the orthographic projection of the boundary B1 and the orthographic projection of the first wire 111, away from the display region AA, among the two adjacent first wires 111 is greater than or equal to 3 microns, so that the first barrier dam D1 has a sufficient interval from the first wire 111.

For example, FIG. 7A also shows a case that the orthographic projection of the boundary B1 of the first barrier dam D1 away from the display region AA on the base substrate 110 is within the orthographic projection of the interval between two adjacent first wires 111 among the plurality of first wires 111 on the base substrate 110, and the distance L1 between the orthographic projection of the boundary B1 and the orthographic projection of the first wire 111, away from the display region AA, among the two adjacent first wires 111 is greater than or equal to 3 microns, and FIG. 7B is a schematic cross-sectional view of the display substrate in FIG. 7A along a line D-D.

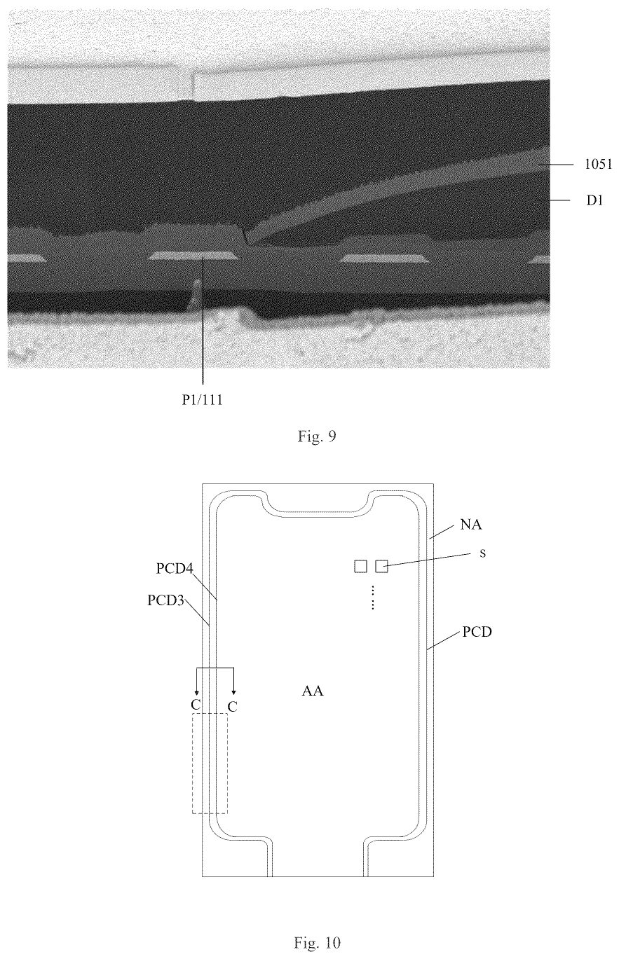

Through the above arrangement, the inorganic encapsulation layer formed above the first barrier dam D1 can be prevented from being broken at the boundary positions of the first wires 111. For example, in the case that the orthographic projection of the boundary B1 of the first barrier dam D1 away from the display region AA on the base substrate 110 is within the orthographic projection of the interval between two adjacent first wires 111 among the plurality of first wires 111 on the base substrate 110, and the distance L1 between the orthographic projection of the boundary B1 and the orthographic projection of the first wire 111, away from the display region AA, among the two adjacent first wires 111 on the base substrate 110 is relatively small, for example, less than 3 microns, as illustrated by FIG. 9, the first inorganic encapsulation layer 1051 (described in detail later) formed above the first barrier dam D1 is easy to break around the first wire 111, thus affecting the encapsulation effect of the display substrate. Through the above arrangement of the embodiments of the present disclosure, the risk of breakage of the first inorganic encapsulation layer 1051 can be fully avoided, and the encapsulation effect of the display substrate can be improved.

For example, in some embodiments, as illustrated by FIG. 2, the crack detection circuit PCD include circuits that detect whether there is a crack in the display substrate using two principles, namely, a bright line detection circuit PCD1 and a resistance detection circuit PCD2. The bright line detection circuit PCD1 may be connected to some sub-pixels through a bright line detection data line PD, and detect whether the bright line detection circuit PCD1 is open by detecting whether the sub-pixels can be lit, so as to infer whether there is a crack in the display substrate. The resistance detection circuit PCD2 includes, for example, two ends, and detects whether the resistance detection circuit PCD2 is open by detecting the level of resistance, so as to infer whether there is a crack in the display substrate. For example, the bright line detection circuit PCD1 and the resistance detection circuit PCD2 may be connected to a circuit board FPC and control the detection process through the circuit board FPC.

For example, in some embodiments, as illustrated by FIG. 2, the display region AA includes a plurality of sub-pixels S, and each of the plurality of sub-pixels S includes a light emitting device EM and a pixel driving circuit for driving the light emitting device EM. The pixel driving circuit may include a plurality of thin film transistors and a storage capacitor, for example, may be formed into various structures such as 2T1C (including two thin film transistors and one storage capacitor), 7T1C (including seven thin film transistors and one storage capacitor), 8T2C (including eight thin film transistors and two storage capacitors), etc. The embodiments of the present disclosure do not limit the specific form of the pixel driving circuit.

For example, FIG. 5A shows a partial schematic cross-sectional view of a sub-pixel S. As illustrated by FIG. 5A, the pixel driving circuit includes a thin film transistor T and a storage capacitor C. The thin film transistor C includes an active layer 1021 and a gate electrode 1022 arranged on the base substrate 110, and source-drain electrodes 1023 and 1024 arranged on a side of the gate electrode 1022 away from the base substrate 110. The storage capacitor C includes a first capacitor electrode 1031 arranged on the base substrate 110 and a second capacitor electrode 1032 arranged on a side of the first capacitor electrode 1031 away from the base substrate 110. The gate electrode 1022 and the first capacitor electrode 1031 are arranged in the same layer, the second capacitor electrode 1032 and the first wiring portion P1 are arranged in the same layer, and the source-drain electrodes 1023 and 1024, the first power signal line VSS and the second wiring portion P2 are arranged in the same layer. Therefore, the manufacturing process of the display substrate can be simplified.

For example, the light emitting device EM includes a first electrode layer 1041 (e.g., an anode layer), a light-emitting material layer 1042, and a second electrode layer 1043 (e.g., a cathode layer). For example, the first electrode layer 1041 is electrically connected to the pixel driving circuit (for example, the source-drain electrode 1023 of the thin film transistor T), and the second electrode layer 1043 is electrically connected to the first power signal line VSS. Driven by voltages applied by the first electrode layer 1041 and the second electrode layer 1043, the light-emitting material layer 1042 can emit light.

For example, FIG. 6A shows another schematic plan view of the display substrate in FIG. 2 in a dashed frame region, and FIG. 6B is a schematic cross-sectional view of the display substrate in FIG. 6A along a line B-B. As illustrated by FIG. 6A and FIG. 6B, in some embodiments, the display substrate may further include a crack barrier dam D3, for example, include a plurality of crack barrier dams D3, five crack barrier dams D3 are shown as an example in FIG. 6A and FIG. 6B, and the crack barrier dam D3 is arranged on a side of the crack detection circuit PCD away from the display region AA and at least partially surrounds the display region AA. The crack barrier dam D3 can block the formation and propagation of cracks, for example, the cracks are prevented from forming when the display substrate is cut or the cracks already formed are prevented from propagating to the display region AA, thus protecting the display substrate in the peripheral region NA.

For example, in some embodiments, the peripheral region NA includes an inorganic layer IN, and the crack barrier dam D3 includes a groove GV disposed in the inorganic layer IN. Because most cracks are generated in the inorganic layer under the action of stress and propagate in the inorganic layer, etching part of the inorganic layer, for example, forming a plurality of inorganic grooves, can effectively prevent microcracks from propagating to the display region AA. For example, the inorganic layer IN may be arranged in the same layer as at least one (for example, all) of a first gate insulating layer 1014A, a second gate insulating layer 1014B and an interlayer insulating layer 1015. For example, the crack barrier dam D3 is covered by part of a planarization layer 1016 to protect the crack barrier dam D3.

It should be noted that, in order to show conciseness, the first gate insulating layer 1014A, the second gate insulating layer 1014B, the interlayer insulating layer 1015, a barrier layer 1112, a buffer layer 1013, the base substrate 110 and the like are not illustrated in FIG. 4 and FIG. 6B, and the following FIG. 7B and FIG. 8B, respectively, and for the stacking relationship of these structures, please refer to FIG. 5A and FIG. 5B.

For example, in some embodiments, as illustrated by FIG. 2, the display substrate may further include a second power signal line VDD. The first power signal line VSS is configured to provide a first power signal to the display region AA, and the second power signal line VDD is configured to provide a second power signal to the display region AA. The potential of the second power signal is higher than the potential of the first power signal, that is, the second power signal is a high-level signal and the first power signal is a low-level signal.

For example, in some embodiments, as illustrated by FIG. 2, the peripheral region NA of the display substrate may further include wire fan-out regions F1/F2, a bending region B, an integrated circuit IC, and the like. The wire fan-out region F1/F2 includes a plurality of connection wires to connect a plurality of lead-out lines (such as data lines) of the display region AA to the integrated circuit IC, and the bending region B has good flexibility to arrange the integrated circuit IC and the circuit board FPC to a non-display side of the display substrate by bending, thereby realizing the narrow border design.

For example, in some embodiments, as illustrated by FIG. 5A and FIG. 5B, the display region further includes the planarization layer 1016 arranged on a side of the pixel driving circuit away from the base substrate 110, a pixel definition layer 1017 arranged on a side of the planarization layer 1016 away from the base substrate 110, and a spacer 1018 arranged on a side of the pixel definition layer 1017 away from the base substrate. The planarization layer 1016 can planarize the pixel driving circuit. The pixel definition layer 1017 includes a plurality of sub-pixel openings PO, which expose the first electrode layers 1041 of the plurality of light emitting devices EM respectively to define light emitting regions of the sub-pixels. The spacer 1018 can have the function of spacing and supporting, such as supporting a device such as a mask that may be used in the manufacturing process.

For example, the first barrier dam D1 may be arranged in the same layer as at least one of the planarization layer 1016, the pixel definition layer 1017 and the spacer 1018. For example, in some embodiments, as illustrated by FIG. 4, the first barrier dam D1 may include three sub-layers D11/D12/D13, which are respectively arranged in the same layer as the planarization layer 1016, the pixel definition layer 1017 and the spacer 1018, so as to simplify the manufacturing process of the display substrate.

For example, in other embodiments, as illustrated by FIG. 5B, the display substrate further includes a connection electrode CEL arranged on a side of the pixel driving circuit away from the base substrate, the connection electrode CEL electrically connects the pixel driving circuit with the first electrode layer 1041. In this case, another planarization layer 1019 is arranged on a side of the connection electrode CEL away from the base substrate. For example, the first barrier dam D1 may be arranged in the same layer as at least one of the planarization layer 1016, the another planarization layer 1019, the pixel definition layer 1017 and the spacer 1018. For example, in the manufacturing process, the pixel definition layer 1017 and the spacer 1018 can be formed by the same patterning process using a gray mask to simplify the manufacturing process of the display substrate. For example, in the case that the planarization layer 1016 or the another planarization layer needs to form portions with different thicknesses in the display substrate, it is also possible to form the portions with different thicknesses by the same patterning process using a gray mask.

For example, in some embodiments, the display substrate further includes a second barrier dam D2, the second barrier dam D2 is arranged on a side of the first barrier dam D1 close to the display region AA and at least partially surrounds the display region AA. For example, the second barrier dam D2 may also be arranged in the same layer as at least one of the planarization layer 1016, the planarization layer 1019, the pixel definition layer 1017 and the spacer 1018.

For example, a height of the first barrier dam D1 relative to the base substrate 110 is greater than a height of the second barrier dam D2 relative to the base substrate 110. For example, in some embodiments, as illustrated by FIG. 4, the second barrier dam D2 may include two sub-layers, which are respectively arranged in the same layer as two of the planarization layer 1016, the planarization layer 1019, the pixel definition layer 1017 and the spacer 1018, so as to simplify the manufacturing process of the display substrate. For example, the second barrier dam D2 includes two sub-layers D21 and D22, the sub-layer D21 is arranged in the same layer as the planarization layer 1016 or the planarization layer 1019 and the sub-layer D22 is arranged in the same layer as the pixel definition layer 1017 or the spacer 1018. The first barrier dam D1 and the second barrier dam D2 have the function of multi-barrier to improve the barrier effect.

For example, in some embodiments, the crack detection circuit PCD may only include the first wiring portion P1, and in this case, the number (length) of the first wiring portion P1 may be appropriately reduced to avoid electrostatic interference. For example, FIG. 8A shows a case where the crack detection circuit PCD only includes the first wiring portion P1, and FIG. 8B is a schematic cross-sectional view of the display substrate in FIG. 8A along a line E-E. As illustrated by FIG. 8A and FIG. 8B, the crack detection circuit PCD only includes the first wiring portion P1 and does not include the second wiring portion P2, and the first wiring portion P1 includes four first wires 111, which can also realize the crack detection function by bright line detection and/or resistance detection, etc. The technical solution can further shorten the distance between the first barrier dam D1 and the cutting line CL and narrow the border.

For example, as illustrated by FIG. 5A and FIG. 5B, the display substrate may further include the barrier layer 1112 and the buffer layer 1013 arranged on the base substrate 110. The barrier layer 1112 and the buffer layer 1013 can prevent impurities in the base substrate 110 from entering multiple functional layers on the display substrate 110, thereby having the protecting function. For example, the barrier layer 1112 and the buffer layer 1013 may be made of inorganic insulating materials such as silicon oxide, silicon nitride or silicon oxynitride.

For example, as illustrated by FIG. 5A and FIG. 5B, the display substrate may further include the first gate insulating layer 1014A arranged on a side of the active layer 1021 away from the base substrate 110, the second gate insulating layer 1014B arranged on a side of the gate electrode 1022 and the first capacitor electrode 1031 away from the base substrate 110, and the interlayer insulating layer 1015 arranged on a side of the second capacitor electrode 1032 away from the base substrate 110. For example, the first gate insulating layer 1014A, the second gate insulating layer 1014B and the interlayer insulating layer 1015 may be made of inorganic insulating materials such as silicon oxide, silicon nitride or silicon oxynitride.

For example, as illustrated by FIG. 5A and FIG. 5B, the display substrate may further include an encapsulation layer EN arranged on a side of the light emitting device EM away from the base substrate 110, and the encapsulation layer EN may be a composite encapsulation layer including a first inorganic encapsulation layer 1051, a first organic encapsulation layer 1052 and a second inorganic encapsulation layer 1053. The first inorganic encapsulation layer 1051 and the second inorganic encapsulation layer 1053 may adopt inorganic insulating materials such as silicon oxide, silicon nitride or silicon oxynitride. The first organic encapsulation layer 1052 may adopt organic insulating materials such as resin and polyimide.

For example, in the embodiments of the present disclosure, the base substrate 110 may be a flexible substrate such as polyimide, and the gate electrode 1022 may adopt a metal material such as copper (Cu), aluminum (Al), titanium (Ti), molybdenum (Mo) or an alloy material, for example, may be formed in a single-layer metal layer structure or a multi-layer metal layer structure such as titanium/aluminum/titanium. The first source-drain electrode 1023 and the first source-drain electrode 1024 may adopt a metal material such as copper (Cu), aluminum (Al), titanium (Ti), molybdenum (Mo) or an alloy material, for example, may be formed in a single-layer metal layer structure or a multi-layer metal layer structure such as titanium/aluminum/titanium. The materials of the first capacitor electrode 1031 and the second capacitor electrode 1032 include a metal material such as aluminum, titanium, cobalt, copper or an alloy material. The active layer 1021 may adopt polysilicon, metal oxide and the like.

For example, the planarization layer 1016, the pixel definition layer 1017, the spacer layer 1018, and the first organic encapsulation layer 1052 of the encapsulation layer EN can adopt organic insulating materials such as polyimide and resin.

For example, as illustrated by FIG. 6B, FIG. 7B and FIG. 8B, in some embodiments, the second electrode layer 1043 of the light emitting device EM may be formed on a whole surface of the display substrate, thus extending from the display region to the peripheral region NA, and the peripheral region NA may further include an electrode material layer 1041A and a light-emitting material 1042A, which are respectively arranged in the same layer as the first electrode layer 1041 and the light-emitting material layer 1042 of the light emitting device EM.

For example, a gate scanning drive circuit GOA is also arranged in the peripheral region NA, and the gate scanning drive circuit GOA also includes structures such as a thin film transistor and a storage capacitor, which may be arranged in the same layer as the structures such as the thin film transistor T and the storage capacitor C of the pixel driving circuit in the display region AA. The peripheral region NA may further include some wires W, which may be arranged in the same layer as the connection electrode CEL.

For example, the display substrate may further include other structures besides the above-mentioned structures. For details, please refer to the related art, which will not be repeated here.

In addition, it should be noted that the material of each functional layer is not limited in the embodiments of the present disclosure, and the material of each functional layer is not limited to the above examples. In the embodiments of the present disclosure, each thin film transistor may be a P-type thin film transistor or an N-type thin film transistor, and the structure of each thin film transistor may be a bottom gate type, a top gate type or a double gate type. The structure illustrated by the attached drawings is only exemplary, and the specific form of each thin film transistor is not limited in the embodiments of the present disclosure.

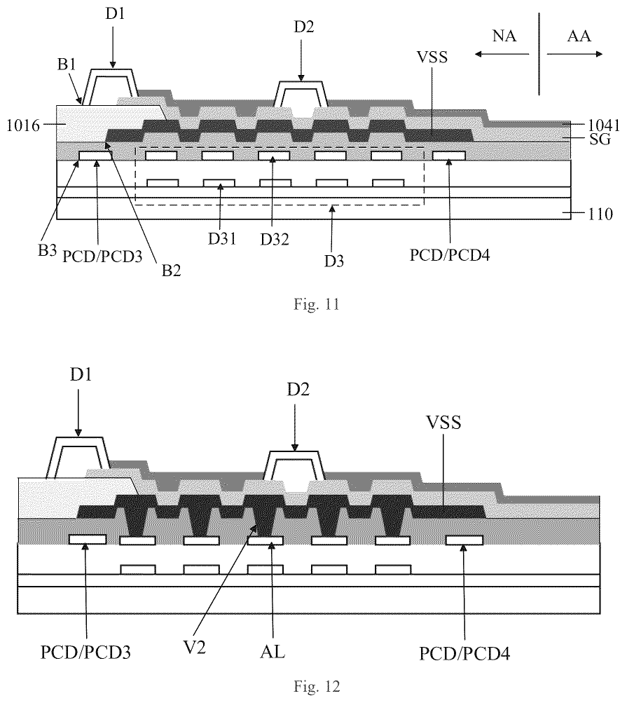

For example, FIG. 10 shows a schematic plan view of another display substrate provided by at least one embodiment of the present disclosure, which mainly shows an arrangement of the crack detection circuit PCD, and FIG. 11 shows a schematic cross-sectional view of the display panel in FIG. 10 along a line C-C.

As illustrated by FIG. 10 and FIG. 11, the display substrate includes a display region AA and a peripheral region NA at least partially surrounding the display region AA, and includes a base substrate 110, a first barrier dam D1, a first power signal line VSS and a crack detection circuit PCD.

The first barrier dam D1 is arranged on the base substrate 110 and in the peripheral region NA, and at least partially surrounds the display region AA, to block materials formed in the display region AA from flowing into the peripheral region NA, for example. The first power signal line VSS is arranged between the base substrate 110 and the first barrier dam D1, and extends at least in the peripheral region NA, for example, from the display region AA to the peripheral region NA in some embodiments. The orthographic projection of at least part of the boundary B2 of the first power signal line VSS away from the display region AA on the base substrate 110 is located inside the orthographic projection of the first barrier dam D1 on the base substrate 110. Thus, the first barrier dam D1 covers the at least part of the boundary B2 of the first power signal line VSS away from the display region AA.

The crack detection circuit PCD is arranged between the base substrate 110 and the first barrier dam D1, and is arranged in the peripheral region NA, and at least partially surrounds the display region AA. The crack detection circuit PCD can detect whether there is a crack in the display substrate. The orthographic projection of the crack detection circuit PCD on the base substrate 110 at least partially overlaps with the orthographic projection of the first barrier dam D1 on the base substrate 110.

For example, in some embodiments, the orthographic projection of at least part of a boundary B3 of the crack detection circuit PCD away from the display region AA on the base substrate 110 is located inside the orthographic projection of the first barrier dam D1 on the base substrate 110. That is, the whole structure of the crack detection circuit PCD is located on a side of the boundary B1 of the first barrier dam D1 close to the display region AA, the boundary B1 is the boundary of the first barrier dam D1 away from the display region AA.

For example, in some embodiments, as illustrated by FIG. 11, the crack detection circuit PCD includes a first portion PCD3 and a second portion PCD4, the first portion PCD3 and the second portion PCD4 may be connected end to end to form one detection circuit, or the first portion PCD3 and the second portion PCD4 may also be two detection circuits respectively. For example, the second portion PCD4 is located on a side of the first portion PCD3 close to the display region AA. For example, an orthographic projection of the first portion PCD3 on the base substrate 110 is located inside the orthographic projection of the first barrier dam D1 on the base substrate 110. The second portion PCD4 is located on a side of the first barrier dam D1 close to the display region AA.

For example, in some embodiments, the orthographic projection of the crack detection circuit PCD on the base substrate 110 at least partially overlaps with the orthographic projection of the first power signal line VSS on the base substrate 110. Therefore, the crack detection circuit PCD and the first power signal line VSS occupy basically the same space on the base substrate 110, so as to achieve the effect of fully utilizing the arrangement space, which is beneficial to the narrow border design.

For example, in some embodiments, the first power signal line VSS is arranged on a side of the crack detection circuit PCD away from the base substrate 110.

For example, as illustrated by FIG. 10, the display region AA includes a plurality of sub-pixels S, each of the sub-pixels S includes a light emitting device EM and a pixel driving circuit for driving the light emitting device EM. Referring to FIG. 5A and FIG. 5B, the display region AA includes the plurality of sub-pixels S, each of the sub-pixels S includes the light emitting device EM and the pixel driving circuit for driving the light emitting device EM, and the pixel driving circuit includes a thin film transistor T and a storage capacitor C, the thin film transistor T includes a gate electrode 1022 arranged on the base substrate 110 and source-drain electrodes 1023 and 1024 arranged on a side of the gate electrode 1022 away from the base substrate 110. The storage capacitor C includes a first capacitor electrode 1031 arranged on the base substrate 110 and a second capacitor electrode 1032 arranged on a side of the first capacitor electrode 1031 away from the base substrate 110, and the gate electrode 1022 and the first capacitor electrode 1031 are arranged in the same layer. For other structures of the light emitting device EM and the pixel driving circuit, please refer to FIG. 5A and FIG. 5B and the descriptions thereof, which will not be repeated here.

For example, the crack detection circuit PCD is arranged in the same layer as the second capacitor electrode 1032, and the first power signal line VSS is arranged in the same layer as the source-drain electrodes 1023 and 1024 to simplify the manufacturing process of the display substrate.

For example, in some embodiments, as illustrated by FIG. 5B, the light emitting device EM is electrically connected with the pixel driving circuit through a connection electrode CEL, and as illustrated by FIG. 11, the display substrate further includes a wire SG arranged on a side of the first power signal line VSS away from the base substrate 110, and includes an electrode material layer 1041A in the same layer as the first electrode layer 1041, and for example, the wire SG is arranged in the same layer as the connection electrode CEL, and the electrode material layer 1041A is a material layer formed in the peripheral region when the first electrode layer 1041 is formed.

For example, in some embodiments, as illustrated by FIG. 12, the peripheral region NA further includes at least one auxiliary wire AL, for example, a plurality of auxiliary wires AL (five auxiliary wires AL are shown as an example in the figure), and the first power signal line VSS is electrically connected with the at least one auxiliary wire AL through a via V2 to be connected in parallel with the at least one auxiliary wire AL. By connecting the auxiliary wire AL in parallel with the first power signal line VSS, a resistance of the first power signal line VSS and a voltage drop of the transmission signal can be reduced, thereby reducing the difference of the signals provided for sub-pixels at different positions.

For example, in some embodiments, the auxiliary wire AL is arranged in the same layer as the crack detection circuit PCD and the second capacitor electrode 1032 to simplify the manufacturing process of the display substrate.

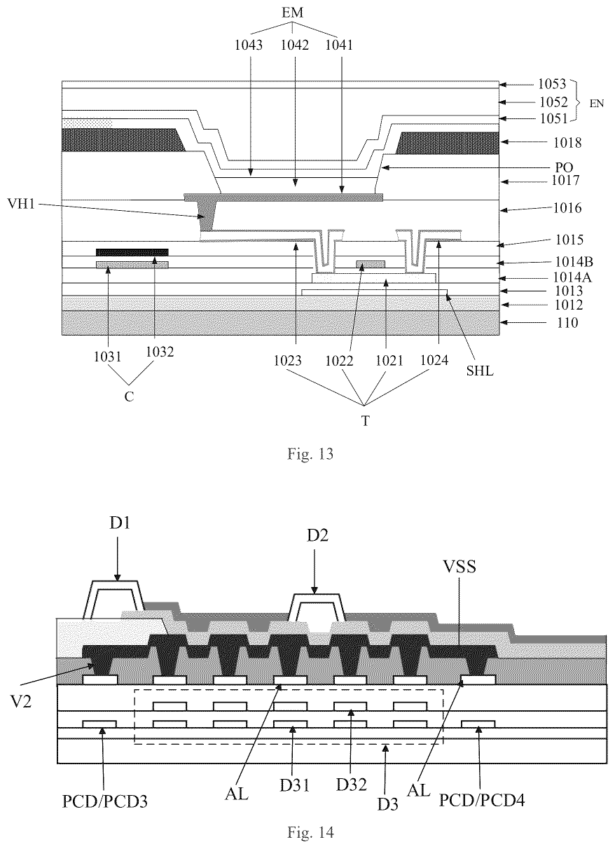

For example, in other embodiments, as illustrated by FIG. 13, the thin film transistor T further includes an active layer 1021, the active layer 1021 is arranged on a side of the gate electrode 1022 close to the base substrate 110, and the display region AA further includes a light shielding pattern SH, the light shielding pattern SH is arranged between the active layer 1021 and the base substrate 110, and an orthographic projection of the active layer 1021 on the base substrate 110 at least partially overlaps with an orthographic projection of the light shielding pattern SH on the base substrate 110. Therefore, the light shielding SH can shield light for the active layer 1021, and prevent light from irradiating the active layer 1021 and affecting the normal operation of the thin film transistor T.

For example, in the above embodiment, as illustrated by FIG. 14, the crack detection circuit PCD may be arranged in the same layer as the light shielding pattern SH to simplify the manufacturing process of the display substrate.

For example, compared with the embodiment of FIG. 12, the embodiment of FIG. 14 may be provided with two more auxiliary wires AL (seven auxiliary wires AL are shown as an example) to further reduce the resistance of the first power signal line VSS and the voltage drop of the transmission signal. As illustrated by FIG. 14, one auxiliary wire AL is arranged above the first portion PCD3 and one auxiliary wire AL is arranged above the second portion PCD4 of the crack detection circuit PCD, and the orthographic projection of the crack detection circuit PCD on the base substrate 110 at least partially overlaps with the orthographic projection of the auxiliary wire AL on the base substrate 110, so that the crack detection circuit PCD and the auxiliary wire AL occupy basically the same region on the display substrate, thereby making full use of the layout space of the display substrate and realizing the narrow border design.

For example, in some embodiments, as illustrated by FIG. 11 and FIG. 14, the display substrate further includes a crack barrier dam D3, for example, a plurality of crack barrier dams D3, and five crack barrier dams D3 are shown as an example. The crack barrier dam D3 is arranged in the peripheral region NA and on a side of the first barrier dam D1 close to the display region AA, at least partially surrounding the display region AA. The crack barrier dam D3 can block the formation and propagation of cracks, for example, block the cracks formed when the display substrate is cut or block the cracks already formed from propagating to the display region AA, thus protecting the display substrate in the peripheral region NA.

For example, the orthographic projection of the crack barrier dam D3 on the base substrate 110 at least partially overlaps with the orthographic projection of the first power signal line VSS on the base substrate 110. For example, the orthographic projection of the crack barrier dam D3 on the base substrate 110 is located within the orthographic projection of the first power signal line VSS on the base substrate 110.

For example, the orthographic projection of the crack barrier dam D3 on the base substrate 110 is located between the orthographic projection of the first portion PCD3 and the orthographic projection of the second portion PCD4 of the crack detection circuit PCD on the base substrate 110, that is, the crack detection circuit PCD can at least partially surround the crack barrier dam D3.

For example, in some embodiments, as illustrated by FIG. 11, the crack barrier dam D3 includes two metal layers D31 and D32, which are arranged in the same layer as the gate electrode 1022 and the second capacitor electrode 1032, respectively, to simplify the manufacturing process of the display substrate. For example, in other embodiments, as illustrated by FIG. 14, the crack barrier dam D3 includes two metal layers D31 and D32, which are respectively arranged in the same layer as the light shielding pattern SH and the gate electrode 1022, so as to simplify the manufacturing process of the display substrate.

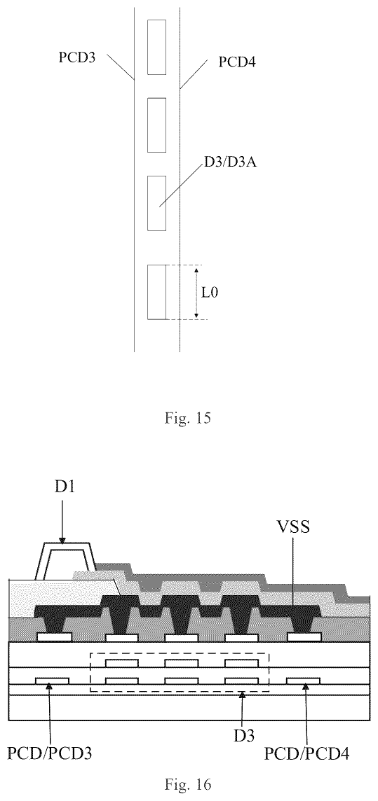

For example, FIG. 15 shows an enlarged schematic view of the display substrate in FIG. 10 in a dashed frame region. As illustrated by FIG. 15, in some embodiments, the crack barrier dam D3 includes a plurality of sub-crack barrier dams D3A arranged at intervals in an extending direction of the crack barrier dam D3, that is, in a vertical direction in the figure.

In research, the inventor(s) of the present disclosure found that if a length of the crack barrier dam D3 is too long, the crack barrier dam D3 is easy to accumulate charges, resulting in a large electrostatic charge that cannot be discharged. Therefore, a tip power generation phenomenon is easy to occur at an end of the crack barrier dam D3, thus melting the metal, leading to oxidation corrosion of the metal. By setting the crack barrier dam D3 to include the plurality of sub-crack barrier dams D3A arranged at intervals, the above-mentioned undesirable phenomena can be avoided.

For example, in some embodiments, in the extending direction of the crack barrier dam D3, a length L0 of each of the plurality of sub-crack barrier dams D3A is less than 50 mm, such as 47 mm, 45 mm or 40 mm, etc. Through an experimental test, under the above conditions, there is basically no undesirable phenomenon such as oxidation corrosion in the crack barrier dam D3.

For example, in some embodiments, as illustrated by FIG. 11, FIG. 12 and FIG. 14, the display substrate further includes a second barrier dam D2, which is arranged on a side of the first barrier dam D1 close to the display region AA and on a side of the crack barrier dam D3 away from the base substrate 110, and the orthographic projection of the crack barrier dam D3 on the base substrate 110 at least partially overlaps with the orthographic projection of the second barrier dam D2 on the base substrate 110.

For example, the height of the first barrier dam D1 relative to the base substrate 110 is greater than the height of the second barrier dam D2 relative to the base substrate 110, so that the first barrier dam D1 and the second barrier dam D2 have the function of double barrier in different positions and to different degrees.

For example, as illustrated by FIG. 11, the planarization layer 1016 is provided below the first barrier dam D1, and therefore the first barrier dam D1 has a relatively greater height. For example, the first barrier dam D1 and the second barrier dam D2 may be arranged in the same layer as at least one of the pixel definition layer 1017, the spacer 1018 or other planarization layers (not shown) arranged on the planarization layer 1016.

For example, in some embodiments, as illustrated by FIG. 16, the display substrate may not include the second barrier dam D2. In this case, the number of the crack barrier dams D3 may be appropriately reduced, and three crack barrier dams D3 are shown as an example in FIG. 16, thereby reducing an area occupied by the crack barrier dams D3 to further narrow the border.

For example, in some embodiments, the display substrate further includes a second power signal line VDD, the first power signal line VSS is configured to provide the first power signal to the display region AA, and the second power signal line VDD is configured to provide the second power signal to the display region AA. The potential of the second power signal is higher than the potential of the first power signal, that is, the second power signal is configured to provide the high-level voltage. For example, the first power signal line VSS is electrically connected with the second electrode layer 1043 of the light emitting device EM to provide the low-level voltage.

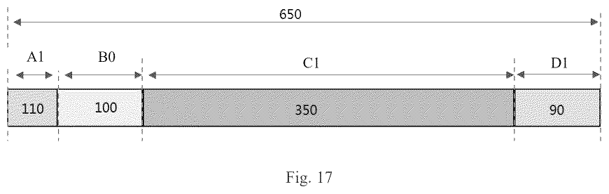

For example, FIG. 17 shows a circuit and structure arrangement of a non-display region NA in a display substrate provided by the embodiments of the present disclosure. As illustrated by FIG. 17, in a direction close to the display region AA, the non-display region NA includes an edge cutting region A1, a crack blocking and power routing region B0, a circuit setting region C1, and a connection region D1. For example, a length of the edge cutting region A1 is about 110 microns; a width of the crack blocking and power routing region B0 is about 100 microns; a width of the circuit setting region C1 is about 350 microns; and a width of the connection region D1 is usually about 90 microns. A total width of each of the above regions is about 650 microns. It can be seen that through the above design of the embodiments of the present disclosure, the border of the display substrate can be further narrowed to achieve the design effect of extremely narrow border.

At least one embodiment of the present disclosure provides a display device, the display device includes any of the above display substrates. For example, the display device may be a mobile phone, a tablet computer, a television, a display, a notebook computer, a digital camera, a navigator and any other product or component with a display function.

The following statements should be noted:
(1) The drawings involve only the structure(s) in connection with the embodiment(s) of the present disclosure, and other structure(s) can be referred to common design(s).
(2) For clarity, in the drawings used to describe the embodiments of the present disclosure, the thicknesses of layers or regions are enlarged or reduced, that is, the drawings are not drawn to actual scale. It can be understood that when a component such as a layer, film, region or substrate is referred to as being “on” or “under” another component, the component may be “directly” “on” or “under” another component, or one or more intermediate components may be interposed therebetween.
(3) In case of no conflict, features in one embodiment or in different embodiments can be combined to obtain new embodiments.

What have been described above are only specific implementations of the present disclosure, the protection scope of the present disclosure is not limited thereto, and the protection scope of the present disclosure should be based on the protection scope of the claims.

1. A display substrate, having a display region and a peripheral region at least partially surrounding the display region, and comprising:
a base substrate;
a first barrier dam, on the base substrate and in the peripheral region, and at least partially surrounding the display region;
a first power signal line, between the base substrate and the first barrier dam and extending at least in the peripheral region, wherein an orthographic projection of at least part of a boundary of the first power signal line away from the display region on the base substrate is located inside an orthographic projection of the first barrier dam on the base substrate; and
a crack detection circuit, between the base substrate and the first barrier dam, in the peripheral region, and at least partially surrounding the display region, wherein an orthographic projection of the crack detection circuit on the base substrate at least partially overlaps with an orthographic projection of the first barrier dam on the base substrate.

2. The display substrate according to claim 1, wherein the crack detection circuit comprises a first wiring portion on the base substrate and a second wiring portion on a side of the first wiring portion away from the base substrate, the second wiring portion is electrically connected with the first wiring portion through a via,
an orthographic projection of the second wiring portion on the base substrate is located inside the orthographic projection of the first barrier dam on the base substrate.

3. The display substrate according to claim 2, wherein the second wiring portion is in a same layer as the first power signal line.

4. The display substrate according to claim 2, wherein the second wiring portion is on a side of the first power signal line away from the display region, and the first wiring portion is on a side of the second wiring portion away from the display region.

5. The display substrate according to claim 2, wherein the first wiring portion comprises a plurality of first wires,
an orthographic projection of a boundary of the first barrier dam away from the display region on the base substrate is located inside an orthographic projection of the plurality of first wires on the base substrate, or
the orthographic projection of the boundary of the first barrier dam away from the display region on the base substrate is located inside an orthographic projection of an interval between two adjacent first wires among the plurality of first wires on the base substrate.

6. The display substrate according to claim 5, wherein the orthographic projection of the boundary of the first barrier dam away from the display region on the base substrate is located in a middle portion of an orthographic projection of one of the plurality of first wires on the base substrate, or
the orthographic projection of the boundary of the first barrier dam on the base substrate is located inside the orthographic projection of the interval between two adjacent first wires among the plurality of first wires on the base substrate, and a distance between the orthographic projection of the boundary of the first barrier dam on the base substrate and an orthographic projection of a first wire, away from the display region, among the two adjacent first wires is greater than or equal to 3 microns.

7. The display substrate according to claim 2, wherein the display region comprises a plurality of sub-pixels, and each of the plurality of sub-pixels comprises a light emitting device and a pixel driving circuit for driving the light emitting device, the pixel driving circuit comprises a thin film transistor and a storage capacitor, the thin film transistor comprises a gate electrode on the base substrate and a source-drain electrode on a side of the gate electrode away from the base substrate, the storage capacitor comprises a first capacitor electrode on the base substrate and a second capacitor electrode on a side of the first capacitor electrode away from the base substrate,
the gate electrode and the first capacitor electrode are in a same layer, the second capacitor electrode and the first wiring portion are in a same layer, and the source-drain electrode and the second wiring portion are in a same layer.

8. The display substrate according to claim 7, further comprising a crack barrier dam, wherein the crack barrier dam is on a side of the crack detection circuit away from the display region.

9. The display substrate according to claim 8, wherein the peripheral region comprises an inorganic layer, and the crack barrier dam comprises a groove in the inorganic layer.

10. The display substrate according to claim 7, wherein the display region further comprises a planarization layer on a side of the pixel driving circuit away from the base substrate, a pixel definition layer on a side of the planarization layer away from the base substrate, and a spacer on a side of the pixel definition layer away from the base substrate,
the first barrier dam is in a same layer as at least one of the planarization layer, the pixel definition layer and the spacer.

11. The display substrate according to claim 1, wherein an orthographic projection of at least part of a boundary of the crack detection circuit away from the display region on the base substrate is located inside the orthographic projection of the first barrier dam on the base substrate.

12. The display substrate according to claim 11, wherein the orthographic projection of the crack detection circuit on the base substrate at least partially overlaps with an orthographic projection of the first power signal line on the base substrate.

13. (canceled)

14. The display substrate according to claim 12, wherein the peripheral region further comprises at least one auxiliary wire, and the first power signal line is electrically connected with the at least one auxiliary wire through a via to be connected in parallel with the at least one auxiliary wire.

15. The display substrate according to claim 14, wherein the display region comprises a plurality of sub-pixels, and each of the plurality of sub-pixels comprises a light emitting device and a pixel driving circuit for driving the light emitting device, the pixel driving circuit comprises a thin film transistor and a storage capacitor, the thin film transistor comprises a gate electrode on the base substrate and a source-drain electrode on a side of the gate electrode away from the base substrate, the storage capacitor comprises a first capacitor electrode on the base substrate and a second capacitor electrode on a side of the first capacitor electrode away from the base substrate,
the gate electrode and the first capacitor electrode are in a same layer, the second capacitor electrode and the at least one auxiliary wire are in a same layer, and the source-drain electrode and the first power signal line are in a same layer.

16. The display substrate according to claim 15, wherein the crack detection circuit and the at least one auxiliary wire are in a same layer.

17. The display substrate according to claim 15, wherein the thin film transistor further comprises an active layer, the active layer is on a side of the gate electrode close to the base substrate, and the display region further comprises a light shielding pattern, the light shielding pattern is between the active layer and the base substrate, and an orthographic projection of the active layer on the base substrate at least partially overlaps with an orthographic projection of the light shielding pattern on the base substrate;
the crack detection circuit and the light shielding pattern are in a same layer.

18. (canceled)

19. The display substrate according to claim 17, wherein the orthographic projection of the crack detection circuit on the base substrate at least partially overlaps with an orthographic projection of the at least one auxiliary wire on the base substrate.

20. The display substrate according to claim 15, further comprising a crack barrier dam, wherein the crack barrier dam is in the peripheral region and on a side of the first barrier dam close to the display region, and at least partially surrounding the display region,
an orthographic projection of the crack barrier dam on the base substrate at least partially overlaps with the orthographic projection of the first power signal line on the base substrate.

21. (canceled)

22. The display substrate according to claim 20, wherein, in an extending direction of the crack barrier dam, the crack barrier dam comprises a plurality of sub-crack barrier dams arranged at intervals.

23. (canceled)

24. The display substrate according to claim 20, further comprising:
a second barrier dam, on a side of the first barrier dam close to the display region and on a side of the crack barrier dam away from the base substrate,
wherein the orthographic projection of the crack barrier dam on the base substrate at least partially overlaps with an orthographic projection of the second barrier dam on the base substrate.

25. (canceled)
